(19) United States
(12) Patent Application Publication
(10) Pub. No.: US 2021/0013729 A1
(43) Pub. Date: Jan. 14, 2021

(54) Battery Charge/Discharge Management Method And System

(71) Applicant: Chung-Fu Chou, Yongkang City (TW)

(72) Inventor: Chung-Fu Chou, Yongkang City (TW)

(21) Appl. No.: 16/505,828

(22) Filed: Jul. 9, 2019

(51) Int. Cl. H02J 7/00; H01M 10/44; H01M 10/42

(52) U.S. Cl. CPC H02J 7/0081; H01M 10/44; H01M 2010/4271; H02J 7/0029; H02J 7/0047; H01M 10/425

(57) ABSTRACT

The present invention relates generally to a battery charge/discharge management method and system. A lithium battery core and a DC/DC converter are embedded in the battery to generate input or output I/O voltage and current. When the lithium battery core is in the working voltage range, the battery charge/discharge management method comprises the following modes: a1. the overvoltage protection mode is adopted when the charging operation is higher than the preset high charging voltage, the I/O voltage cannot be fed in the battery; a2. it is charging mode when the charging operation voltage is lower than the preset high charging voltage and higher than the minimum rechargeable voltage, the I/O voltage can charge the lithium battery core in the battery; a3. it is protection mode when the I/O voltage is lower than the minimum rechargeable voltage and higher than the maximum dischargeable voltage, no charging/discharging operation; a4. the battery can discharge when the I/O voltage is lower than the maximum dischargeable voltage and higher than the minimum dischargeable voltage, the I/O voltage comprises the output internal reference voltage of DC/DC converter and the electric quantity indication voltage of product scaled down according to the actual voltage of lithium battery core, and the I/O voltage corresponds to dynamic load line characteristic; a5. the I/O voltage load line offset is enlarged when the actual voltage of lithium battery core is lower than the preset low battery voltage; a6. it is negative voltage protection mode when the I/O voltage is lower than 0V, the battery does not perform charging/discharging operation, and I/O terminal to ground short circuit provides a negative current loop; the present invention can provide better electric quantity management and measurement.

### BACKGROUND OF INVENTION

### 1. Field of the Invention

The present invention relates generally to a battery charge/discharge management method and system, and more particularly to a chargeable and dischargeable architecture, which can manage the electric quantity indication and export dynamic load line characteristic.

### 2. Description of Related Art

The known dry battery is disposable or rechargeable, the disposable battery is generally Zn—Mn battery, it will be discarded after it is used once, polluting the environment and wasting resources. In addition, the rechargeable battery is mostly Ni—H or Ni—Cd battery, it can be charged when the electric quantity is insufficient, more friendly to the environment and the battery cost is reduced. However, the output voltage of the Ni—H or Ni—Cd battery is about 1.2V, lower than 1.5V of general disposable battery, so that said rechargeable battery may be inapplicable to a part of electric products, and if the electrical equipment uses the series voltage of multiple batteries, the difference between the series voltage of said rechargeable battery and the series voltage of disposable battery will be larger, the applicability of the chargeable battery is reduced.

In order to improve the low voltage of the Ni—H or Ni—Cd rechargeable battery, there is a structure that a lithium battery and a DC/DC converter are located in the battery case, and the 3.0˜4.2V voltage of lithium battery can be converted into 1.5V voltage output, FIG. 6 shows a known architecture, a lithium battery core 11′ is provided in the battery case (not shown in the figure), the lithium battery core 11′ is electrically connected to the battery negative terminal 10′, protective circuit 12′ and DC/DC converter 13′. The DC/DC converter 13′ output is connected to the battery positive terminal 14′, and connected to the charging terminal 15′ in the protective circuit 12′, the charging terminal 15′ is located in the center of case, and it can be provided with a USB terminal (not shown in the figure), it can be used in an external device with a charge controller 16′ to charge the lithium battery core 11′ with 5V voltage.

The charge controller 16′ of said architecture can be located in the battery, and the DC/DC converter 13′ can export about 1.5V voltage corresponding to the disposable battery, and the charging terminal 15′ can detect the electric quantity of built-in lithium battery 11′. However, the battery charging terminal 15′ of the structure must be provided with an additional terminal (e.g. USB terminal) to form a three-terminal architecture, and the positive terminal 14′ is exposed during charging, there are safety risks.

FIG. 7 shows the known structure 2, a lithium battery core 21′ is located in the battery case (not shown in the figure), the lithium battery core 21′ is connected to the negative terminal 20′ and protective circuit 22′, the protective circuit 22′ is electrically connected to the DC/DC converter 23′ and charge controller 24′. The DC/DC converter 23′ and charge controller 24′ are electrically connected to the loop controller 25′, and connected to the battery positive terminal 26′ at the loop controller 25′. In the course of discharge, the lithium battery core 21′ exports 3.0−4.2V voltage to the positive terminal 26′ through protective circuit 22′, DC/DC adapter 23′ and loop controller 25′, and the lithium battery core 21′ can be charged by positive terminal 26′, loop controller 25′, charge controller 24′ and protective circuit 22′.

The architecture can deliver about 1.5V voltage by voltage stabilization setting of DC/DC converter 23′, and charge and discharge via the same positive terminal 26′, it has the same charge mode of conventional rechargeable battery, meeting general charging habit. However, the positive terminal 26′ cannot measure the electric quantity of lithium battery core 21′, so that the positive terminal 26′ of the DC/DC converter 23′ has no output instantaneously when the electric quantity of lithium battery core 21′ is insufficient, and the electrical product using the battery which is not charged instantly is out of use. The instantaneous zero output characteristic is different from the gradual outage of general disposable battery which can be cognized by the user, so the architecture has worse performance than disposable battery in reflecting the outage of battery. In parallel connection, the output voltage error of the DC/DC converter 23′ will result in the unbalance that the parallel discharge only uses higher voltage battery. In series connection, the battery with minimum electric quantity will determine the service time.

### SUMMARY OF THE INVENTION

The primary object of the present invention is to provide a method and architecture of built-in rechargeable lithium battery core with electric quantity indication.

Another object of the present invention is to provide the method and architecture with output dynamic load line characteristic and low battery indication.

In terms of the battery charge/discharge management method of the present invention, a lithium battery core and a DC/DC converter are embedded in the lithium battery to generate I/O voltage and current. When the lithium battery core is in the working voltage range, the battery charge/discharge management method has the following modes: a1. the overvoltage protection mode is adopted when the charging operation is larger than the preset high charging voltage, the I/O voltage cannot be fed in the battery; a2. it is charging mode when the charging operation voltage is lower than the preset high charging voltage and higher than the minimum rechargeable voltage, the I/O voltage can charge the lithium battery core in the battery; a3. it is protection mode when the I/O voltage is lower than the minimum rechargeable voltage and higher than the maximum dischargeable voltage, no charging/discharging operation; a4. when the I/O voltage is lower than the maximum dischargeable voltage and higher than the minimum dischargeable voltage, the battery can discharge, the I/O voltage comprises the internal reference voltage delivered from the DC/DC converter and the electric quantity indication voltage of the product scaled down according to the actual voltage of lithium battery core, and the I/O voltage corresponds to dynamic load line characteristic of the preset output load.

Furthermore, the modes of the management method include a5. when the actual voltage of lithium battery core is lower than the preset low battery voltage, the I/O voltage load line offset is enlarged; a6. it is negative voltage protection mode when the I/O voltage is lower than 0V, the battery does not perform charging/discharging operation, and the I/O terminal to ground short circuit provides a negative current loop.

In the mode a4 of the present invention, when the voltage of lithium battery core is higher than the set value of low battery, and the output I/O current is higher than the electric quantity indication voltage output setting voltage, the I/O voltage=internal reference voltage+electric quantity indication voltage−output load current indication voltage, and the electric quantity indication voltage=((lithium battery core voltage−minimum voltage of lithium battery core)×1/(saturation voltage of lithium battery core−minimum voltage of lithium battery core))×preset range voltage, and the output load current indication voltage corresponds to the output current on a preset output load.

Furthermore, the present invention has an external detection device, the external detection device detects the electric quantity of lithium battery core, comprising the following steps: b1. let the battery I/O output current be lower than the electric quantity indication voltage output setting current, the positive and negative terminals of battery are measured to obtain internal DC/DC converter reference voltage; b2. the external detection device admits the preset load, let the battery output current be higher than the electric quantity indication voltage output setting current, the positive and negative terminals of battery are measured to obtain the measuring voltage; b3. the voltage−internal reference voltage is measured to obtain electric quantity indication voltage, the electric quantity indication voltage is converted into the actual lithium battery core voltage.

In the mode a5 of the present invention, the output load indication voltage corresponds to the output current on several times of the preset output load in Mode a4, so as to enlarge the I/O voltage load line offset.

The battery charge/discharge management system of the present invention comprises a battery case connected to a positive terminal and a negative terminal; a lithium battery core located in the battery case; a charge/discharge management circuit located in the battery case, and electrically connected to the positive and negative terminals of battery and to the anode and cathode of lithium battery core. The charge/discharge management circuit comprises a bidirectional DC/DC converter, electrically connected to the anode and cathode of lithium battery core and to the positive and negative terminals of battery respectively, provided with a multiplexer and core control circuit; a managerial detection circuit, the input side is electrically connected to the anode and cathode of lithium battery core and to the positive and negative terminals of battery, the output side is connected to the multiplexer and core control circuit; and the managerial detection circuit delivers the compound signal of electric quantity of lithium battery core voltage and DC/DC converter output internal reference voltage and preset output load current indication voltage to the multiplexer and core control circuit, and the positive and negative terminals of battery can reflect the lithium battery core voltage.

Furthermore, the bidirectional DC/DC converter has several voltage stabilization switches and a control switch SW1, the managerial detection circuit comprises a first voltage/current buffer amplifier, electrically connected to the lithium battery core, multiplexer and core control circuit; a second voltage/current buffer amplifier, electrically connected to the battery output positive and negative terminals and multiplexer and core control circuit; a charging error amplifier, the difference between lithium battery core voltage and allowable maximum voltage of lithium battery core is amplified and imported into the multiplexer and core control circuit; an electric quantity indication voltage equalizer, the input is electrically connected to the first voltage/current buffer amplifier, the output is connected to a switch SW1, and the output generates detection current; a discharge reference supply synthesizer, connected to switch SW1, the switch SW1 is controlled by the multiplexer and core control circuit, and connected to the electric quantity indication voltage equalizer and discharge reference supply synthesizer, generating the compound signal of electric quantity; a discharging error amplifier, the input side is connected to the second voltage/current buffer amplifier and discharge reference supply synthesizer, the output side is connected to the multiplexer and core control circuit, and the compound signal of electric quantity is fed in the multiplexer and core control circuit.

Furthermore, the managerial detection circuit has a discharging current equalizer, the discharging current equalizer is electrically connected to the multiplexer and core control circuit, a second voltage/current buffer amplifier circuit, and a discharge reference supply synthesizer, the discharging current equalizer has two preset loads at different rates corresponding to non-low battery and low battery of lithium battery core, and the multiplexer and core control circuit selects the preset load according to non-low battery and low battery of lithium battery core to generate different I/O voltage load line slopes.

In terms of the battery capacity measurement method of the present invention, a lithium battery core and a DC/DC converter are embedded in the battery to generate input or output I/O voltage and current. When the lithium battery core is in the working voltage range and the output I/O current is higher than the electric quantity indication voltage output setting current, the I/O voltage=internal reference voltage+electric quantity indication voltage−output load current indication voltage; wherein the electric quantity indication voltage=((lithium battery core voltage−minimum voltage of lithium battery core)×1/(saturation voltage of lithium battery core−minimum voltage of lithium battery core)×preset range voltage, the output load current indication voltage corresponds to the output current on a preset output load; as well as an external detection device, the external detection device detects the electric quantity of lithium battery core, comprising the following steps: b1. let the battery I/O output current be lower than the electric quantity indication voltage output setting current, the positive and negative terminals of battery are measured to obtain internal reference voltage; b2. the external detection device admits preset load, let the battery output current be higher than the electric quantity indication voltage output setting current, the positive and negative terminals of battery are measured to obtain the measuring voltage; b3. measuring voltage−internal reference voltage results in the electric quantity indication voltage, the electric quantity indication voltage is converted into the actual lithium battery core voltage.

The battery of the present invention can be two-terminal architecture as general battery, and the actual electric quantity of internal lithium battery core can be measured at the positive and negative terminals of the battery, so as to avoid the user misidentifying the electric quantity of battery when the electric quantity of lithium battery core is insufficient but the battery output has not decreased (about 1.5V). The present invention is applicable to rapid voltage drop of electrical products, so that the user can know that the lithium battery core is exhausted without measurement, the low battery identification effect is better.

### BRIEF DESCRIPTION OF THE DRAWINGS

FIG. 1 is the schematic diagram of the system architecture of the present invention.

FIG. 2 is the block diagram of the system architecture of the present invention.

FIG. 3 is the circuit diagram of the system architecture of the present invention.

FIG. 4 is the schematic diagram of system operation mode of the present invention.

FIG. 5 is waveform diagram of discharging operation of the present invention.

FIG. 6 is the structural representation of the known lithium battery 1.

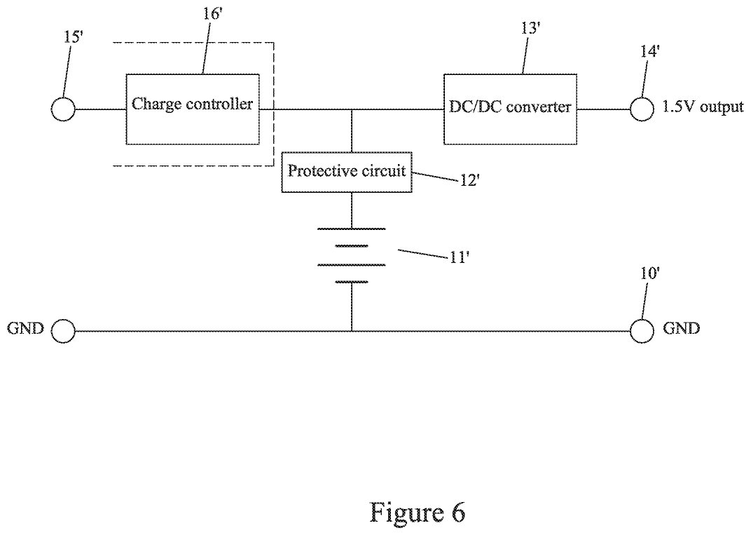

FIG. 7 is the structural representation of the known lithium battery 2.

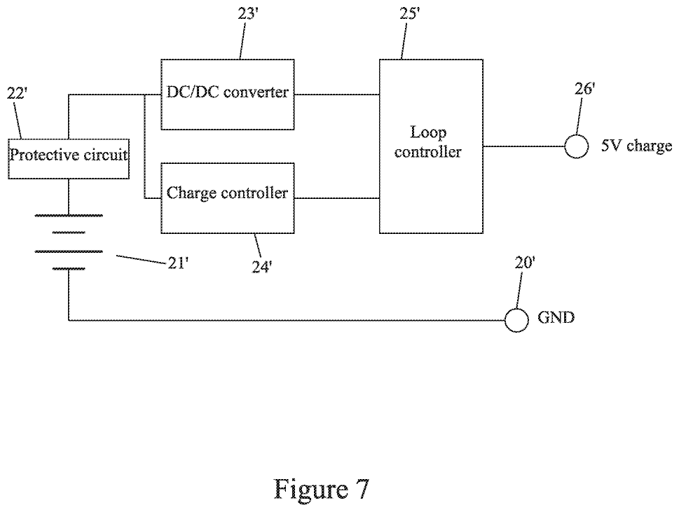

### DETAILED DESCRIPTION OF THE INVENTION

A lithium battery core and a DC/DC converter are embedded in the lithium battery of the present invention to generate input or output I/O voltage and current, when the lithium battery core is in the working voltage range (3V˜4.2V), the battery charge/discharge management method has the following modes:

a1. The overvoltage protection mode is adopted when the charging operation is larger than the preset high charging voltage (about 5.5V), the I/O voltage cannot be fed in the battery.
a2. It is charging mode when the charging operation voltage is lower than the preset high charging voltage and higher than the minimum rechargeable voltage (about 4.5V), the I/O voltage can charge the lithium battery core in the battery.
a3. It is protection mode when the I/O voltage is lower than the minimum rechargeable voltage and higher than the maximum dischargeable voltage (about 1.6V), no charging/discharging operation.
a4. The battery can discharge when the I/O voltage is lower than the maximum dischargeable voltage and higher than the minimum dischargeable voltage (about 1V), the I/O voltage comprises the internal reference voltage delivered from the DC/DC converter and the electric quantity indication voltage Vgauge of product scaled down according to the actual voltage of lithium battery core, and the I/O voltage corresponds to the dynamic load line characteristic of the preset output load.
a5. The I/O voltage load line offset is enlarged when the actual voltage of lithium battery core is lower than the preset low battery voltage Vbat_Low (about 3.2V).
a6. It is negative voltage protection mode when the I/O voltage is lower than 0V, the battery does not perform charging/discharging operation, and the I/O terminal to ground short circuit provides a negative current loop.

In said mode a4, when the lithium battery core voltage Vbat is higher than the set value of low battery (3V) and the output current is higher than the electric quantity indication voltage output setting current (1˜10 mA), the I/O voltage is internal reference voltage (about 1.5V)+an output load current indication voltage Vdrop of electric quantity indication voltage Vgauge.

Wherein the electric quantity indication voltage Vgauge=((lithium battery core voltage Vbat−minimum voltage of lithium battery core Vbat_Dead 3V)×1/(saturation voltage of lithium battery core Vbat_Full 4.2V−minimum voltage of lithium battery core Vbat_Dead))×preset range voltage (Vgauge_max=100 mV in this embodiment, e.g. when the lithium battery core voltage Vbat is 3.6V, the Vgauge voltage is ((3.6−3)×1/(4.2−3))×100 mV=0.05V.

The electric quantity indication voltage Vgauge of the present invention is reduced at the preset ratio according to the proportion of the voltage Vbat of current lithium battery core to the output voltage range of the lithium battery core, so that the electric quantity indication voltage Vgauge is much lower than internal reference voltage (about 1.5V), so the combination of the electric quantity indication voltage Vgauge and the internal reference voltage of battery (about 1.5V) will not increase the output I/O voltage greatly (maximum 1.6V in this embodiment), applicable to general electrical equipment.

In terms of dynamic load line characteristic corresponding to output voltage I/O in mode a4 of the present invention, the output load Rest is set when the lithium battery core voltage Vbat is higher than the low voltage of lithium battery (3.2V), when the output current is higher than the electric quantity indication voltage output setting current (1˜10 mA), the offset for the preset load line is calculated according to the battery output current to generate the output load current indication voltage Vdrop, so that the output I/O voltage of the positive and negative terminals of the battery is internal reference voltage (about 1.5V)+an output load current indication voltage Vdrop of electric quantity indication voltage Vgauge.

The output load current indication voltage Vdrop must be corresponding to the output current on a preset output load Rset when the lithium battery core voltage Vbat is lower than the maximum dischargeable voltage (about 1.6V) and higher than the minimum dischargeable voltage (about 1V), and with the corresponding dynamic negative voltage load line slope.

The present invention can be combined with an external detection device to detect the electric quantity of lithium battery core. The external detection device is a special detection device for the battery product of the present invention, it can be sold with the battery product of the present invention. The external detection device detects the electric quantity of lithium battery core through the following steps:
b1. Let the battery I/O output current be lower than the electric quantity indication voltage Vgauge output setting current (1˜10 mA), the positive and negative terminals of battery are measured to obtain the reference voltage V01 of internal DC/DC converter.
b2. The external detection device admits preset load, let the battery output I/O current be higher than the electric quantity indication voltage Vgauge output setting current (1˜10 mA), the positive and negative terminals of battery are measured to obtain the measuring voltage V02.
b3. The measuring voltage V02−internal reference voltage V01 results in electric quantity indication voltage Vgauge, the electric quantity indication voltage Vgauge is converted by said electric quantity indication voltage Vgauge into the actual lithium battery core voltage Vbat.

Wherein in step b1, the internal reference voltage V01 of battery is measured first to avoid large bias error in the electric quantity indication voltage Vgauge obtained in step b3 when the reference voltage V01 of the internal DC/DC converter deviates from the ideal voltage (1.5V) largely.

When the electric quantity indication voltage Vgauge is obtained in step b3, the lithium battery core voltage Vbat can be obtained from the equation in mode a4.

The output load indication voltage Vdrop in mode a5 of the present invention is the voltage corresponding to several times of preset output load N in mode a4×output I/O current on Rset, so that the I/O voltage can be reduced rapidly according to internal reference voltage (about 1.5V)+an output load current indication voltage Vdrop (the Vdrop increases) of electric quantity indication voltage (Vgauge), and the internal resistance increases in the simulation of low battery of chemical cell, and the user can know the insufficient electric quantity of lithium battery core from the connected electric device directly without detection instruments (e.g. the luminance of flashlight drops rapidly, the user can know the electric quantity of lithium battery core is insufficient).

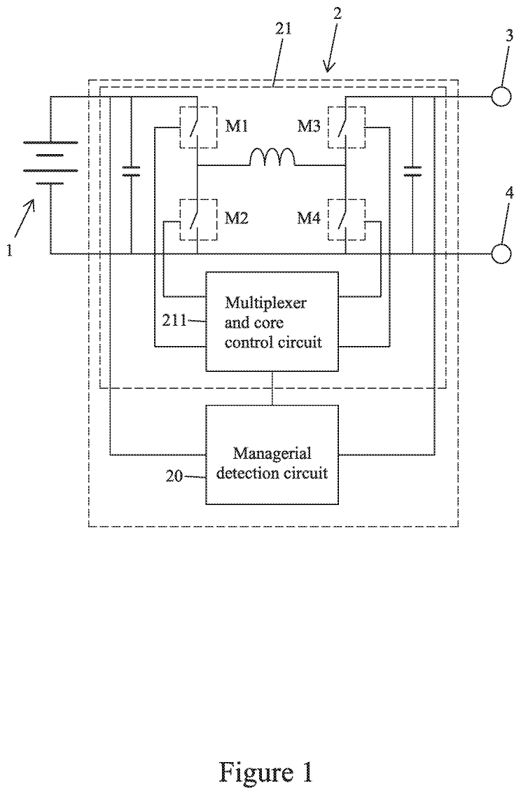

As shown in FIG. 1, the system of the present invention comprises a battery case (not shown in the figure), a lithium battery core 1, a charge/discharge management circuit 2, the battery case is connected to a positive terminal 3 and a negative terminal 4; and the lithium battery core 1 is located in the battery case; the charge/discharge management circuit 2 is located in the battery case, and electrically connected to the positive and negative terminals 3, 4 and lithium battery core 1, and it controls the external power supply to deliver and reduce voltage to charge the lithium battery core 1 via the positive and negative terminals 3, 4 or reduce the voltage of lithium battery core 1 to discharge via the positive and negative terminals 3, 4.

The charge/discharge management circuit 2 comprises a DC/DC converter 21 and a managerial detection circuit 20. The DC/DC converter 21 is electrically connected to the anode and cathode of lithium battery core 1 and to the anode and cathode terminals 3, 4 of battery respectively, provided with a multiplexer and core control circuit 211, the input side of the managerial detection circuit 20 is electrically connected the anode and cathode of lithium battery core 1 and the anode and cathode terminals 3, 4 of battery, the output side is connected to the multiplexer and core control circuit 211; and the managerial detection circuit 20 feeds the compound signal of electric quantity of voltage of lithium battery core 1 and the output internal reference voltage and preset output load current indication voltage of DC/DC converter 211 in the multiplexer and core control circuit 211, and the anode and cathode terminals 3, 4 of battery can reflect the voltage of lithium battery core 1.

As shown in FIGS. 1 to 3, the DC/DC converter 21 has a control switch SW1, and the managerial detection circuit 20 comprises a first voltage/current buffer amplifier 22 corresponding to the lithium battery core 1 terminal, a second voltage/current buffer amplifier 23 corresponding to the battery output terminal, a charging error amplifier 24, an electric quantity indication voltage equalizer 25, a discharge reference supply synthesizer 26, a discharging error amplifier 27 and a discharging current equalizer 28.

The DC/DC converter 21 is a bidirectional buck charge/discharge controller, electrically connected to the anode and cathode of lithium battery core 1 and the battery output positive and negative terminals 3, 4 respectively. The DC/DC converter 21 has two mosfet switches M1, M2 connected in series, two mosfet switches M3, M4 connected in series, a multiplexer and core control circuit 211, two capacitors corresponding to the lithium battery core 1 and the positive and negative terminals 3, 4 of battery respectively, a switch SW1, the switches M1, M2 are electrically connected to the anode and cathode of lithium battery core 1 respectively, the switches M3, M4 are electrically connected to the battery output positive and negative terminals 3, 4 respectively, and an inductor is located between switches M1, M2 and between switches M3, M4, the multiplexer and core control circuit 211 controls M1, M2, M3 and M4 to perform PWM voltage stabilization output action, and the switch SW1 is controlled by the multiplexer and core control circuit 211, it can be used for electrical connection between the electric quantity indication voltage equalizer 25 and the discharge reference synthesizer 26.

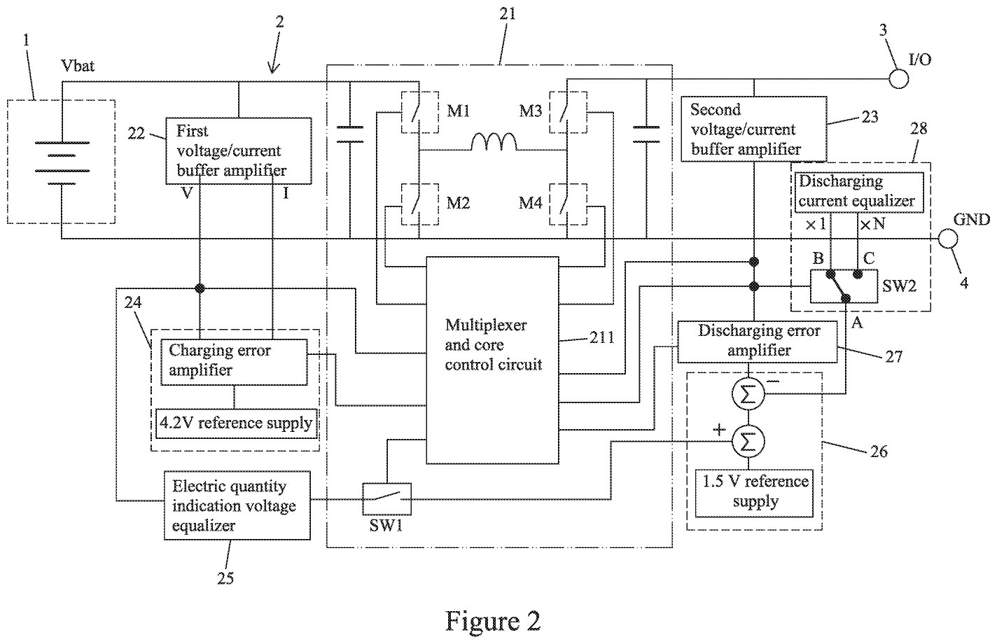

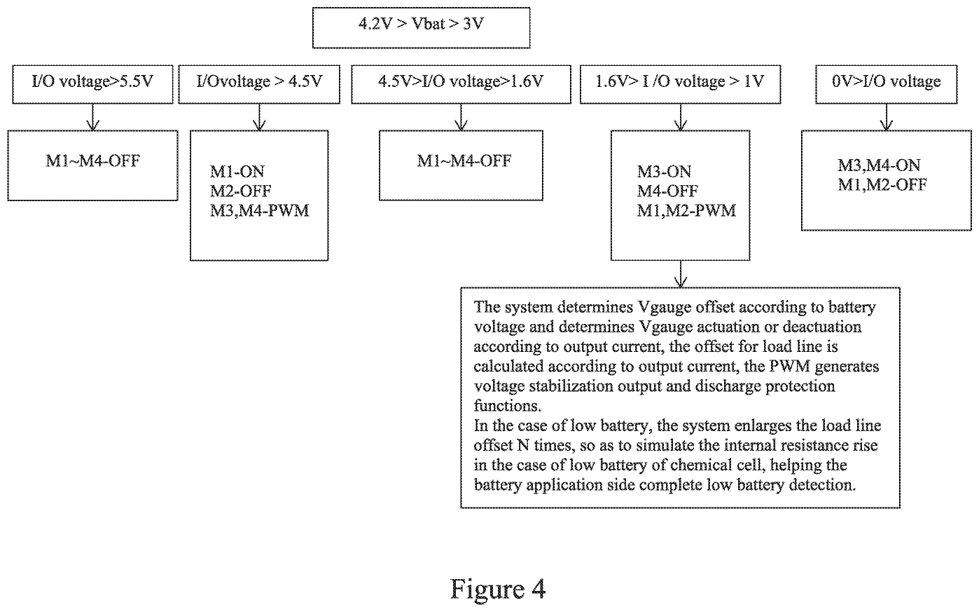

As shown in FIGS. 2 to 4, the DC/DC converter 21 makes switches M1˜M4 OFF when the I/O voltage is higher than the preset high charging voltage 5.5V in said mode a1; in the mode a2, the output I/O voltage between the preset high charging voltage (about 5.5V) and minimum rechargeable voltage (about 4.5V) is defined as charging mode, switch M1 ON, M2 OFF, M3 and M4 perform PWM action, and the external power supply charges the lithium battery core 1 with constant voltage.

In the mode a3 of the present invention, when the battery voltage is minimum rechargeable voltage (about 4.5V) to maximum dischargeable voltage (about 1.6V), switches M1 M4 OFF; in the mode a4 of the present invention, when the I/O voltage is maximum to minimum dischargeable voltage (1.6V˜1V), switch M3 ON, M4 OFF, and switches M1, M2 perform PWM voltage stabilization action. In the mode a6, the output I/O voltage is lower than 0, it is negative voltage protection mode, switches M3, M4 ON, switches M1, M2 OFF, and the input voltage performs reverse connection of battery to protect cathode short circuit.

The first voltage/current buffer amplifier 22 of the present invention is electrically connected to the lithium battery core 1, the second voltage/current buffer amplifier 23 is electrically connected to the positive and negative terminals 3, 4 of I/O voltage, and the voltage Vbat and current of lithium battery core 1 of lithium battery core 1 terminal and the I/O voltage and current of battery output positive and negative terminals 3, 4 can be amplified respectively and fed in the multiplexer and core control circuit 211, the second voltage/current buffer amplifier 23 has a sensing resistor R3 connected to battery output in series.

The input of charging error amplifier 24 is connected to the voltage Vbat of lithium battery core 1 and the maximum voltage of lithium battery core (Vbat_Full 4.2V), the input is connected to the multiplexer and core control circuit 211, the difference from the voltage Vbat of lithium battery core 1 and maximum voltage 4.2V of lithium battery core is amplified and fed in the multiplexer and core control circuit 211, the multiplexer and core control circuit 211 can control the switches M1˜M4 to charge the lithium battery core 1 in charging mode.

The input side of electric quantity indication voltage equalizer 25 is electrically connected the first voltage/current buffer amplifier 22, the output is connected to the switch SW1 and discharge reference supply synthesizer 26. The output of the electric quantity indication voltage equalizer 25 is combined with the discharge reference supply synthesizer 26 to generate the compound signal of electric quantity of I/O voltage=internal reference voltage+electric quantity indication voltage Vgauge−output load current indication voltage Vdrop to the discharging error amplifier 27, delivered by the discharging error amplifier 27 to the multiplexer and core control circuit 211, so that the system actuates switches M1˜M4 to generate I/O voltage in discharge mode.

The electric quantity indication voltage equalizer 25 has a first operational amplifier OP1, a mosfet M0, a resistor R0, two mosfet M8, M9, the R0 is connected to the output terminal of the first voltage/current buffer amplifier 22 and the input terminal of OP1, the other input terminal of the OP1 corresponds to the dead voltage Vbat_Dead 3V of lithium battery core 1, and the OP1 output is connected to the G pole of M0, the S pole and D pole of the M0 are connected to the resistor and R0 and M0 D pole, the M8 and M9 form a current mirror circuit, the M9 D pole is connected to switch SW1, so the R0, M0 and the node E of input OP1 generate 3V voltage corresponding to the other input terminal of OP1, and the difference between the voltage Vbat of lithium battery core 1 and dead voltage Vbat_Dead 3V of lithium battery core 1 generates detection current Igauge on R0.

The discharge reference supply synthesizer 26 is connected to switch SW1 and discharging current equalizer 28, the switch SW1 is controlled by the multiplexer and core control circuit 211, and connected to the electric quantity indication voltage equalizer 25 and discharge reference supply synthesizer 26. The switch SW1 is turned on when the multiplexer and core control circuit 211 generates electric quantity indication voltage output setting current (1 mA). The discharge reference supply synthesizer 26 comprises a second operational amplifier OP2, a resistor R4, one end of the resistor R4 is connected to switch SW1, the other end is connected to an input terminal and an output terminal of OP2; the input terminal of the OP2 is connected to a 1.5V reference supply, and the input detection current Igauge of the electric quantity indication voltage equalizer 25 and R4 generate Igauge×R4 upward offset, the R0, M8 and M9 current mirror coupling ratio and R4 are set to make the offset equal to

((Vbat−Vbat_Dead)×1/(Vbat_Full−Vbat_Dead))×Vgauge_max.

The output of the OP2 is connected to the discharging error amplifier 27, and the discharging current equalizer 28 comprises two operational amplifiers OP3, OP4, mosfet M5, M6, M7, resistors R8, R9, R10, R11, the M6 and M7 form a current mirror circuit, and the output is connected to the OP2 input terminal of discharge reference supply synthesizer 26. One end of the M6 S pole is connected to the circuit system power supply Vcc, the M6 D pole is connected to M5 D pole, the M5 S pole is connected to resistor R11 and grounded, the output terminal of the OP3 is connected to the M5 G pole, one input terminal is connected to the node H between M5 S pole and R11. Another input terminal of the OP3 is connected to the output terminal of OP4. One input terminal of the OP4 is connected to the rate switching circuit composed of R8, R9, R10 and switch SW2. The R10 is connected to an input terminal and an output terminal of OP4. One end of the R8 and R9 is connected to one input terminal of OP4, the other end is connected to SW2 and grounded. The SW2 is controlled by the multiplexer and core control circuit 211 to ground R8 or R9. Another input terminal of the OP4 is connected to the output of the second voltage/current buffer amplifier 23 corresponding to the sensing resistor R3 to amplify output potential.

The multiplexer and core control circuit 211 of the present invention actuates the SW2 according to the voltage Vbat of lithium battery core 1, so that the OP4 can generate OP4 output F node output voltage according to the preset rate and the input voltage of the second voltage/current buffer amplifier 23. The F node voltage VF is converted by OP3 to make R11 and node H of M5 have the corresponding F voltage, and the preset current Idrop of VF÷R11 is generated, the preset current mirror Idrop is fed in the OP2 input side of discharge reference supply synthesizer through current M6, M7, and Idrop×R4 downward offset is generated, the R3; M6 and M7 current mirror coupling ratio, R10 and R11 can be set to make the reference voltage component output offset meet Vdrop=Iout×Rset.

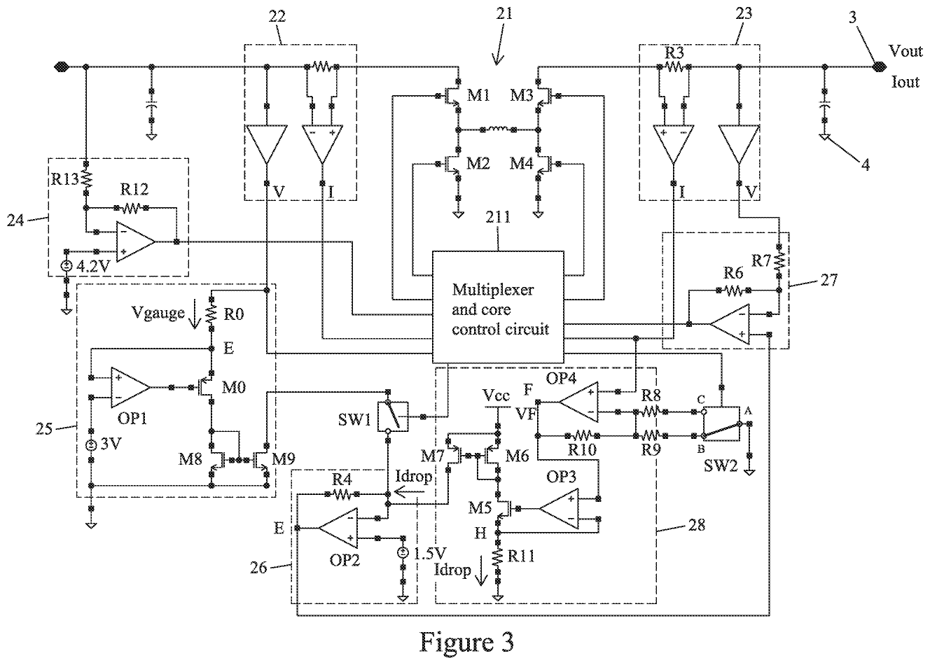

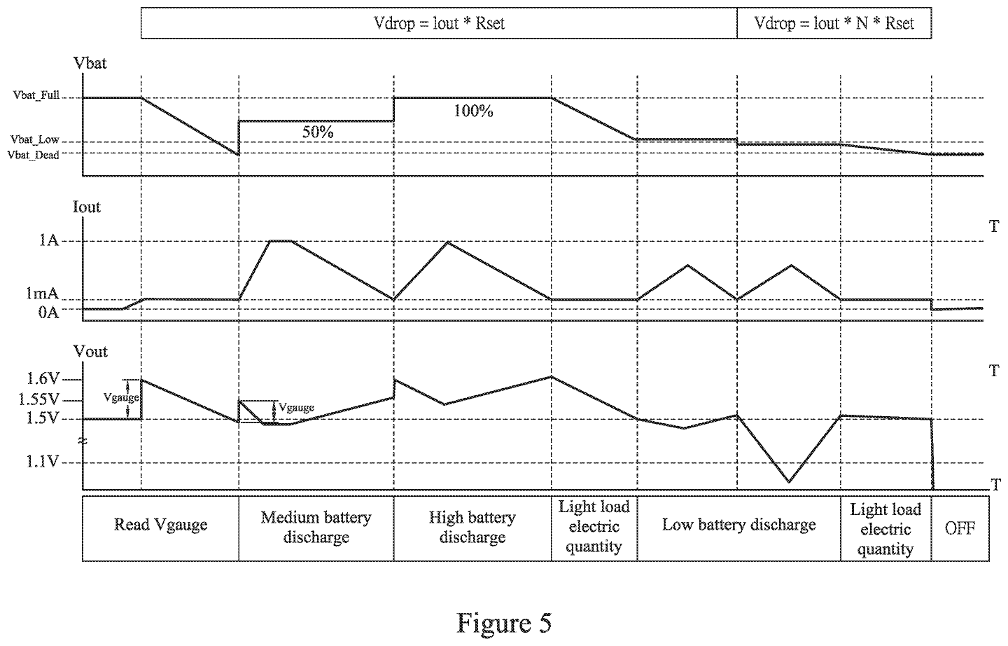

The waveform of the present invention is shown in FIG. 2 and FIG. 5, the center Iout in FIG. 5 is fictitious load, when the multiplexer and core control circuit 211 generates 1 mA, the output voltage Vout generates electric quantity indication voltage Vgauge. As shown in the left side of FIG. 5, when the electric quantity Vbet of lithium battery core 1 is maximum electric quantity Vbat_Full, the Vgauge voltage is 0.1V, so Vout is 1.6V, when the electric quantity Vbat of battery core is 50%, the Vgauge is, and Vout is 1.55V. The Vout forms the dynamic load line characteristic slope on the horizontal line corresponding to the internal reference voltage according to output current variation. The output load current indication voltage Vdrop=output current Iout×sensing resistor Rset, the switch SW2 A, B in FIG. 2, FIG. 3 are turned on.

When the electric quantity Vbat of the lithium battery core 1 is low battery Vbat_Low, the multiplexer and core control circuit 211 turns on switch SW2 A, C, the output load current indication voltage is output current Iout×N times of sensing resistor Rset, so the output voltage Vout drops at a large slope to a level lower than low battery voltage 1.1V, so that the user can know the power condition immediately when using the electric product. The multiplexer and core control circuit 211 can recover the Vout to light load electric quantity after the rapid drop of Vout, so as to enable the electric product to use the residual electric quantity.

The multiplexer and core control circuit of the present invention can deliver electric quantity indication voltage Vgauge in the case opposite to the aforesaid embodiment and no load and Iout set as 0, there is no electric quantity indication voltage Vgauge when the internal preset current 1 mA is exceeded, the setting has the effect of the present invention on measuring the electric quantity of lithium battery core.

The battery of the present invention can be two-terminal architecture as general battery, and the actual electric quantity of internal lithium battery core can be measured at the anode and cathode terminals of the battery, the measurement is convenient, so as to avoid the user misidentifying the electric quantity of battery when the electric quantity of lithium battery core is insufficient but the battery output has not decreased (about 1.5V). The present invention is applicable to rapid voltage drop of electrical products, so that the user can know that the lithium battery core is exhausted without measurement, the battery identification effect is better.

In series connection of the battery of the present invention, at the end of discharge of one battery, the switches M3, M4 are turned on in mode M6 to form a low-loss loop, and the series connected battery is still workable, the series connection safety is better.

Therefore, the present invention can enhance the electric quantity review and use safety of lithium battery, and can reduce the consumption of disposable battery greatly. Said embodiments are examples of the present invention, not to limit the present invention, any equivalent changes within the spirit of the present invention shall be in the scope of the present invention.

The specific embodiments have been described, there may be modifications and changes within the technical scope of the present invention, the scope of the present invention limits the attached claims.

1. A battery charge/discharge management method, a lithium battery core and a DC/DC converter are embedded in the battery to generate input or output I/O voltage and current, when the lithium battery core is in the working voltage range, the battery charge/discharge management method has the following modes:
a1. the overvoltage protection mode is adopted when the charging operation is larger than the preset high charging voltage, the I/O voltage cannot be fed in the battery;
a2. it is charging mode when the charging operation voltage is lower than the preset high charging voltage and higher than the minimum rechargeable voltage, the I/O voltage can charge the lithium battery core in the battery;
a3. it is protection mode when the I/O voltage is lower than the minimum rechargeable voltage and higher than the maximum dischargeable voltage, no charging/discharging operation;
a4. the battery can discharge when the I/O voltage is lower than the maximum dischargeable voltage and higher than the minimum dischargeable voltage, the I/O voltage comprises the internal reference voltage delivered from the DC/DC converter and the electric quantity indication voltage of product scaled down according to the actual voltage of lithium battery core, and the I/O voltage corresponds to the dynamic load line characteristic of the preset output load.

2. The battery charge/discharge management method defined in claim 1, wherein the management method has the following modes: a5. the I/O voltage load line offset is enlarged when the actual voltage of lithium battery core is lower than the preset low battery voltage;
a6. it is negative voltage protection mode when the I/O voltage is lower than 0V, the battery does not perform charging/discharging operation, and the I/O terminal to ground short circuit provides a negative current loop.

3. The battery charge/discharge management method defined in claim 1, wherein in the mode a4, when the lithium battery core voltage is higher than the set value of low battery and the output I/O current is higher than the electric quantity indication voltage output setting current, the I/O voltage is equal to internal reference voltage+electric quantity indication voltage−output load current indication voltage.

4. The battery charge/discharge management method defined in claim 3, wherein the electric quantity indication voltage=((lithium battery core voltage−minimum voltage of lithium battery core)×1/(saturation voltage of lithium battery core−minimum voltage of lithium battery core))×preset range voltage, the output load current indication voltage corresponds to the output current on a preset output load.

5. The battery charge/discharge management method defined in claim 4, wherein there is an external detection device, the external detection device detects the electric quantity of lithium battery core, comprising the following steps:
b1. let the battery I/O output current be lower than the electric quantity indication voltage output setting current, the anode and cathode terminals of battery are measured to obtain internal reference voltage;
b2. the external detection device admits the preset load, let the battery output current be higher than the electric quantity indication voltage output setting current, the anode and cathode terminals of battery are measured to obtain the measuring voltage;
b3. measuring voltage−internal reference voltage results in electric quantity indication voltage, the electric quantity indication voltage is converted into the actual lithium battery core voltage.

6. The battery charge/discharge management method defined in claim 2, wherein the output load indication voltage in the mode a5 is the voltage corresponding to the output current on several times of preset output load in the mode a4, so as to enlarge the I/O voltage load line offset.

7. A battery charge/discharge management system, comprising a battery case connected to a positive terminal and a negative terminal;
a lithium battery core located in the battery case;
a charge/discharge management circuit located in the battery case, electrically connected to the positive and negative terminals of battery and the anode and cathode of lithium battery core, the charge/discharge management circuit comprises:
a DC/DC converter, electrically connected to the anode and cathode of lithium battery core and positive and negative terminals of battery, provided with a multiplexer and core control circuit;
a managerial detection circuit, the input side is electrically connected to the anode and cathode of lithium battery core and the positive and negative terminals of battery, the output side is connected to the multiplexer and core control circuit;
the managerial detection circuit feeds the compound signal of electric quantity of lithium battery core voltage and DC/DC converter output internal reference voltage and preset output load current indication voltage in the multiplexer and core control circuit, and the positive and negative terminals of battery can reflect the lithium battery core voltage.

8. The battery charge/discharge management system defined in claim 7, wherein the DC/DC converter comprises several voltage stabilization switches and a control switch SW1, the managerial detection circuit comprises:
a first voltage/current buffer amplifier, electrically connected to the lithium battery core and multiplexer and core control circuit;
a second voltage/current buffer amplifier, electrically connected to the battery output positive and negative terminals and multiplexer and core control circuit;
a charging error amplifier, the difference between the lithium battery core voltage and allowable maximum voltage of lithium battery core is amplified and fed in the multiplexer and core control circuit;
an electric quantity indication voltage equalizer, the input is electrically connected to the first voltage/current buffer amplifier, the output is connected to a switch SW1, and the output generates detection current;
a discharge reference supply synthesizer, connected to switch SW1, the switch SW1 is controlled by the multiplexer and core control circuit, and connected to the electric quantity indication voltage equalizer and discharge reference supply synthesizer, generating the compound signal of electric quantity;
a discharging error amplifier, the input side is connected to the second voltage/current buffer amplifier and discharge reference supply synthesizer, the output side is connected to the multiplexer and core control circuit, and the compound signal of electric quantity is fed in the multiplexer and core control circuit.

9. The battery charge/discharge management system defined in claim 8, wherein the managerial detection circuit has a discharging current equalizer, the discharging current equalizer is electrically connected to the multiplexer and core control circuit, a second voltage/current buffer amplifier circuit, and a discharge reference supply synthesizer, the discharging current equalizer has two preset loads at different rates corresponding to non-low battery and low battery of lithium battery core, and the multiplexer and core control circuit selects the preset load according to non-low battery and low battery of lithium battery core to generate different I/O voltage load line slopes.

10. The battery charge/discharge management system defined in claim 8, wherein the voltage stabilization switch of the DC/DC converter has two mosfet switches M1, M2 connected in series, two mosfet switches M3, M4 connected in series, a multiplexer and core control circuit, two capacitors corresponding to the lithium battery core and the positive and negative terminals of battery respectively, a switch SW1, the switches M1, M2 are electrically connected to the anode and cathode of lithium battery core respectively, the switches M3, M4 are electrically connected to the battery output positive and negative terminals respectively, and an inductor is located between switches M1, M2 and between switches M3, M4, the multiplexer and core control circuit controls M1, M2, M3 and M4 to perform PWM voltage stabilization output action.

11. A battery charge/discharge management method, a lithium battery core and a DC/DC converter are embedded in the battery to generate input or output I/O voltage and current, when the lithium battery core is in the working voltage range and the output I/O current is higher than the electric quantity indication voltage output setting current, the I/O voltage=internal reference voltage+electric quantity indication voltage−output load current indication voltage;
wherein the electric quantity indication voltage=((lithium battery core voltage−minimum voltage of lithium battery core)×1/(saturation voltage of lithium battery core−minimum voltage of lithium battery core))×preset range voltage, and the output load current indication voltage corresponds to the output current on a preset output load;
there is an external detection device, the external detection device detects the electric quantity of lithium battery core, comprising the following steps:
b1. let the battery I/O output current be lower than the electric quantity indication voltage output setting current, the positive and negative terminals of battery are measured to obtain internal reference voltage;
b2. the external detection device admits the preset load, let the battery output current be higher than the electric quantity indication voltage output setting current, the positive and negative terminals of battery are measured to obtain the measuring voltage.
b3. measuring voltage−internal reference voltage results in electric quantity indication voltage, the electric quantity indication voltage is converted into the actual lithium battery core voltage.

12. A battery charge/discharge management method, a lithium battery core and a DC/DC converter are embedded in the battery to generate input or output I/O voltage and current, when the lithium battery core is in the working voltage range, the battery charge/discharge management method has the following modes:
a1. the overvoltage protection mode is adopted when the charging operation is larger than the preset high charging voltage, the I/O voltage cannot be fed in the battery;
a2. it is charging mode when the charging operation voltage is lower than the preset high charging voltage and higher than the minimum rechargeable voltage, the I/O voltage can charge the lithium battery core in the battery;
a3. it is protection mode when the I/O voltage is lower than the minimum rechargeable voltage and higher than the maximum dischargeable voltage, no charging/discharging operation;
a4. the battery can discharge when the I/O voltage is lower than the maximum dischargeable voltage and higher than the minimum dischargeable voltage, the I/O voltage comprises the internal reference voltage delivered from the DC/DC converter and the electric quantity indication voltage of product scaled down according to the actual voltage of lithium battery core, and the I/O voltage corresponds to the dynamic load line characteristic of the preset output load;
a5. the I/O voltage load line offset is enlarged when the actual voltage of lithium battery core is lower than the preset low battery voltage;
a6. it is negative voltage protection mode when the I/O voltage is lower than 0V, the battery does not perform charging/discharging operation, and the I/O terminal to ground short circuit provides a negative current loop.

13. The battery charge/discharge management method defined in claim 12, wherein in the mode a4, when the lithium battery core voltage is higher than the set value of low battery and the output I/O current is higher than the electric quantity indication voltage output setting current, the I/O voltage=internal reference voltage+electric quantity indication voltage−output load current indication voltage; and the electric quantity indication voltage=((lithium battery core voltage−minimum voltage of lithium battery core)×1/(saturation voltage of lithium battery core−minimum voltage of lithium battery core))×preset range voltage, the output load current indication voltage corresponds to the output current on a preset output load.

14. The battery charge/discharge management method defined in claim 12, wherein there is an external detection device, the external detection device detects the electric quantity of lithium battery core, comprising the following steps:
b1. let the battery I/O output current be lower than the electric quantity indication voltage output setting current, the positive and negative terminals of battery are measured to obtain internal reference voltage;
b2. the external detection device admits the preset load, let the battery output current be higher than the electric quantity indication voltage output setting current, the positive and negative terminals of battery are measured to obtain the measuring voltage.
b3. measuring voltage−internal reference voltage results in electric quantity indication voltage, the electric quantity indication voltage is converted into the actual lithium battery core voltage.

15. The battery charge/discharge management method defined in claim 12, wherein the output load indication voltage in the mode a5 is the voltage corresponding to the output current on several times of preset output load in the mode a4, so as to enlarge the I/O voltage load line offset.
